(19) United States
(12) Patent Application Publication
(10) Pub. No.: US 2016/0260547 A1
(43) Pub. Date: Sep. 8, 2016

(54) MULTILAYER CERAMIC CAPACITOR AND BOARD HAVING THE SAME

(71) Applicant: SAMSUNG ELECTRO-MECHANICS CO., LTD., Suwon-Si (KR)

(72) Inventors: Heung Kil PARK, Suwon-Si (KR); Chang Su KIM, Suwon-Si (KR)

(21) Appl. No.: 14/953,075

(22) Filed: Nov. 27, 2015

(30) Foreign Application Priority Data
Mar. 5, 2015 (KR) 10-2015-0031177

(51) Int. Cl. H01G 4/30; H05K 1/18; H05K 1/11; H01G 4/005

(52) U.S. Cl. CPC H01G 4/30; H01G 4/005; H05K 1/181; H05K 1/111

(57) ABSTRACT

A multilayer ceramic capacitor includes: a ceramic body including a plurality of dielectric layers and first and second internal electrodes disposed to be alternately exposed in a length direction with at least one of the dielectric layers interposed therebetween; first and second external electrodes disposed on opposite end portions of the ceramic body in the length direction and connected to the first and second internal electrodes, respectively; and first and second insulating layers disposed on central portions of body portions of the first and second external electrodes to be perpendicular to a mounting surface of the ceramic body, respectively.

### CROSS-REFERENCE TO RELATED APPLICATION

This application claims the priority and benefit of Korean Patent Application No. 10-2015-0031177 filed on Mar. 5, 2015, with the Korean Intellectual Property Office, the disclosure of which is incorporated herein by reference.

### BACKGROUND

The present disclosure relates to a multilayer ceramic capacitor and a board having the same.

A multilayer ceramic capacitor (MLCC), a multilayer electronic component, may be used in various electronic apparatuses due to advantages such as compact size, high capacitance, and ease of mounting.

For example, the multilayer ceramic capacitor is mounted on printed circuit boards of various electronic products including display devices such as liquid crystal displays (LCDs), plasma display panels (PDPs), and the like, as well as including computers, smartphones, mobile phones, and personal digital assistants (PDAs) to serve to charge and discharge electricity.

The multilayer ceramic capacitor may have a structure in which a plurality of dielectric layers and internal electrodes disposed between the dielectric layers and having different polarities are alternately stacked.

Since the dielectric layers have piezoelectric and electrostrictive properties, when direct current (DC) voltage or alternating current (AC) voltage is applied to the multilayer ceramic capacitor, a piezoelectric phenomenon may occur between the internal electrodes to generate periodical vibrations while expanding and contracting a volume of a ceramic body depending on a frequency.

These vibrations maybe transferred to a printed circuit board on which the multilayer ceramic capacitor is mounted through external electrodes of the multilayer ceramic capacitor and solders connecting the external electrodes and the board to each other, and thus the entirety of the board becomes an acoustic reflective surface to generate a vibration sound, which is noise.

The vibration sound may be within an audio frequency range of 20 to 20,000 Hz, which may cause listener discomfort and is referred to as acoustic noise.

Further, in recent electronic devices, a mechanical component has been made silent, and therefore acoustic noise generated in the multilayer ceramic capacitor as described above may become more prominent.

In a case in which the device is operated in a silent environment, a user may consider the acoustic noise a device flaw.

In addition, in a device having an audio component, acoustic noise overlaps audio output, and thus the quality of the device may be deteriorated.

### SUMMARY

An aspect of the present disclosure may provide a multilayer ceramic capacitor capable of decreasing acoustic noise, and a board having the same.

According to an aspect of the present disclosure, a multilayer ceramic capacitor may include: internal electrodes stacked perpendicularly to amounting surface of a ceramic body; and insulating layers disposed on central portions of body portions of external electrodes to be perpendicular to the mounting surface.

According to another aspect of the present disclosure, a multilayer ceramic capacitor may include: a ceramic body including a plurality of dielectric layers and first and second internal electrodes disposed to be alternately exposed in a length direction with at least one of the dielectric layers interposed therebetween; first and second external electrodes disposed on opposite end portions of the ceramic body in the length direction and connected to the first and second internal electrodes, respectively; and first and second insulating layers disposed on central portions of body portions of the first and second external electrodes to be perpendicular to a mounting surface of the ceramic body, respectively.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a schematic perspective view of a multilayer ceramic capacitor according to an exemplary embodiment in the present disclosure;

FIG. 2 is a cross-sectional view taken along line I-I′ of FIG. 1;

FIG. 3 is an exploded perspective view illustrating an example of the arrangement of internal electrodes of FIG. 1;

FIG. 4 is an exploded perspective view illustrating another example of the arrangement of the internal electrodes of FIG. 1;

FIG. 5 is a perspective view of a multilayer ceramic capacitor according to another exemplary embodiment in the present disclosure;

FIG. 6 is a perspective view of a multilayer ceramic capacitor according to another exemplary embodiment in the present disclosure; and

FIG. 7 is a perspective view of a board having a multilayer ceramic capacitor according to an exemplary embodiment in the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

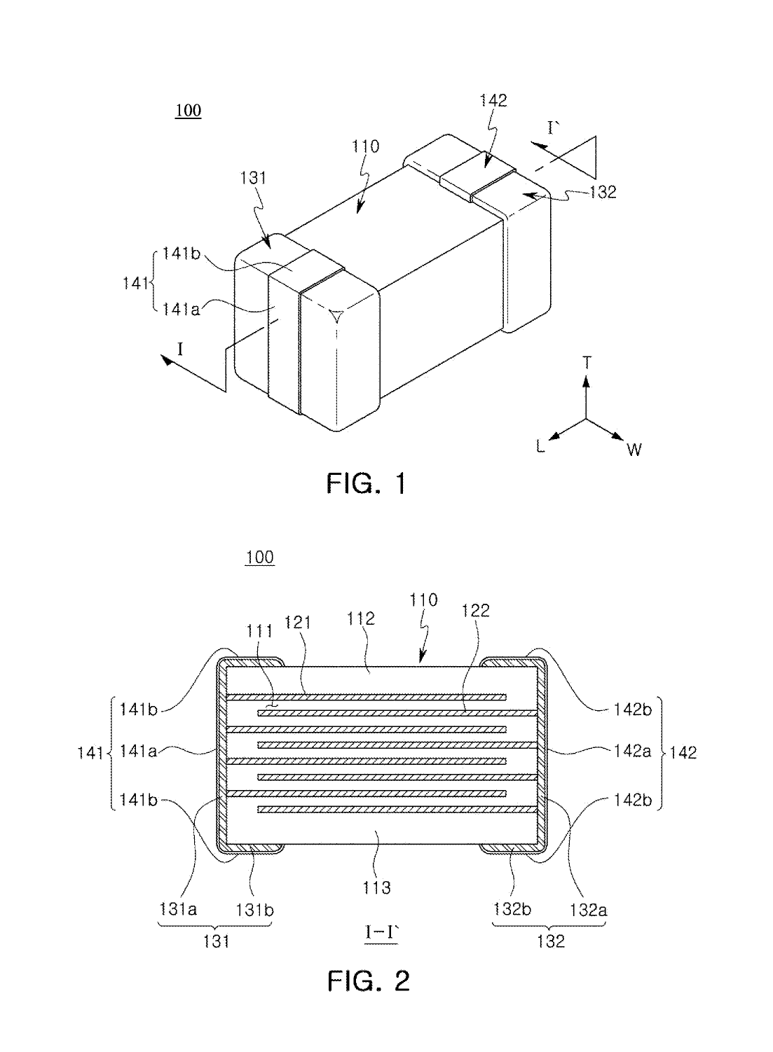

FIG. 1 is a schematic perspective view of a multilayer ceramic capacitor according to an exemplary embodiment, and FIG. 2 is a cross-sectional view taken along line I-I′ of FIG. 1.

Referring to FIGS. 1 and 2, a multilayer ceramic capacitor 100, according to the present exemplary embodiment, may include a ceramic body 110, first and second external electrodes 131 and 132, and first and second insulating layers 141 and 142.

In the present exemplary embodiment, the ceramic body 110 may be formed by stacking a plurality of dielectric layers 111 in a thickness direction T and then sintering the plurality of dielectric layers 111.

Here, respective adjacent dielectric layers 111 of the ceramic body 110 may be integrated with each other so that boundaries therebetween are not readily apparent.

In addition, the ceramic body 110 may have a hexahedral shape. However, a shape of the ceramic body is not limited thereto.

Further, cover layers 112 and 113 having a predetermined thickness may be disposed on the uppermost internal electrode of the ceramic body 110 and below the lowermost internal electrode of the ceramic body 110, respectively, if necessary.

Here, the cover layers 112 and 113 may be formed of the same composition as that of the dielectric layers 111 and may be formed by stacking one or more dielectric layers that do not include internal electrodes in upper and lower portions of the ceramic body 110, respectively.

A thickness of one dielectric layer 111 may be arbitrarily changed depending on a capacitance design of the multilayer ceramic capacitor 100.

In addition, the dielectric layer 111 may contain a high-k ceramic material, such as a barium titanate (BaTiO₃) based ceramic powder. However, a material of the dielectric layer 111 is not limited thereto.

An example of the barium titanate (BaTiO₃) based ceramic powder may include (Ba₁₋ₓCaₓ)TiO₃, Ba (Ti_{1-y}Ca_{y}) O₃, (Ba₁₋ₓCaₓ) (Ti_{1-y}Zr_{y}) O₃, Ba (Ti_{1-y}Zr_{y}) O₃, and the like, in which calcium (Ca), zirconium (Zr), or the like, is partially dissolved in BaTiO₃. However, an example of the barium titanate (BaTiO₃) based ceramic powder is not limited thereto.

Meanwhile, the dielectric layer 111 may further contain a ceramic additive, an organic solvent, a plasticizer, a binder, a dispersant, and the like, in addition to the ceramic powder.

For the ceramic additive, a transition metal oxide or carbide, a rare earth element, magnesium (Mg), aluminum (Al), or the like, may be used.

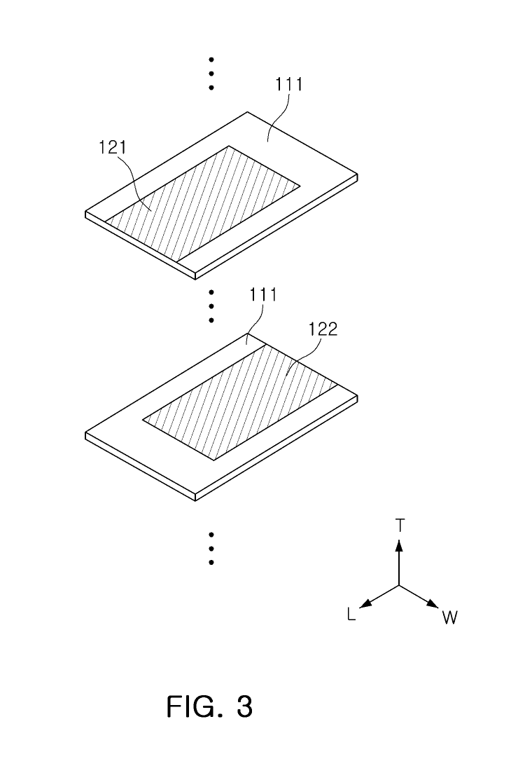

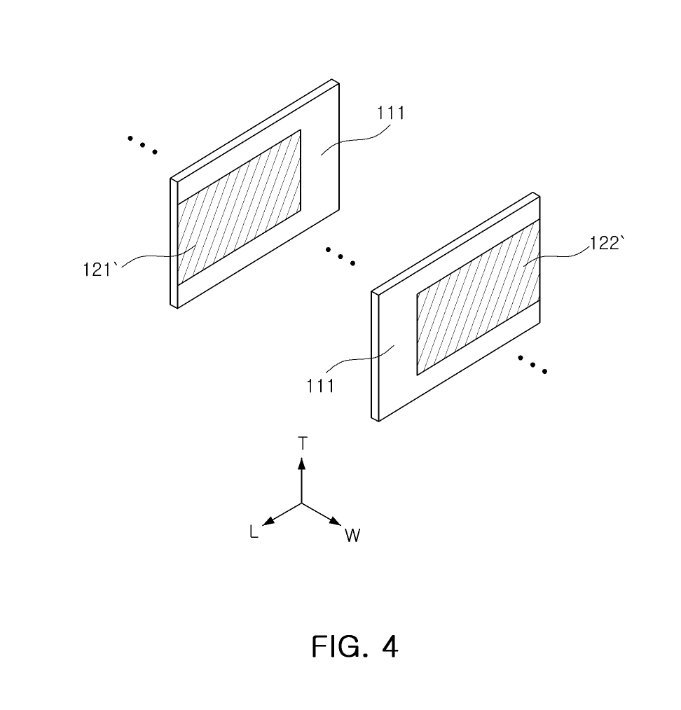

As illustrated in FIG. 3, the first and second internal electrodes 121 and 122 may be formed on ceramic sheets forming the dielectric layers 111, stacked in the thickness direction T, and then sintered, and thus they are alternately disposed in the ceramic body 110 with each of the dielectric layers 111 interposed therebetween.

The first and second internal electrodes 121 and 122 having different polarities may be disposed to face each other in a direction in which the dielectric layers 111 are stacked and may be electrically insulated from each other by the dielectric layers 111 disposed therebetween.

One end portions of the first and second internal electrodes 121 and 122 may be exposed through opposite end surfaces of the ceramic body 110 in a length direction L, respectively.

The end portions of the first and second internal electrodes 121 and 122 alternately exposed through opposite end surfaces of the ceramic body 110 in the length direction L as described above may be electrically connected to the first and second external electrodes 131 and 132 on opposite end surfaces of the ceramic body 110 in the length direction L, respectively.

Here, the first and second internal electrodes 121 and 122 may be formed of a conductive metal, such as nickel (Ni) or a nickel (Ni) alloy. However, materials of the first and second internal electrodes 121 and 122 are not limited thereto.

According to the configuration as described above, when predetermined voltages are applied to the first and second external electrodes 131 and 132, electric charges may be accumulated between the first and second internal electrodes 121 and 122 facing each other.

Here, capacitance of the multilayer ceramic capacitor 100 may be in proportion to an area of a region in which the first and second internal electrodes 121 and 122 overlap each other in the direction in which the dielectric layers 111 are stacked.

Meanwhile, although a multilayer ceramic capacitor in which the first and second internal electrodes 121 and 122 are stacked in the thickness direction T of the ceramic body 110, that is, in parallel with a mounting surface, has been illustrated and described in the present exemplary embodiment, the multilayer ceramic capacitor, according to an exemplary embodiment, is not limited thereto.

For example, as illustrated in FIG. 4, the multilayer ceramic capacitor, according to an exemplary embodiment, may be configured in a manner in which dielectric layers 111 and first and second internal electrodes 121′ and 122′ are stacked in a width direction W of the ceramic body 110, that is, perpendicular to the mounting surface.

The first and second external electrodes 131 and 132 may be formed by firing conductive paste for an external electrode containing, for example, copper (Cu) in order to have good electrical properties and provide high reliability such as excellent heat cycle resistance, moisture resistance, and the like. However, the first and second external electrodes 131 and 132 are not limited to being formed as described above.

The first and second external electrodes 131 and 132 may include first and second body portions 131a and 132a and first and second band portions 131b and 132b, respectively.

The first and second body portions 131a and 132a may cover opposite end surfaces of the ceramic body 110 in the length direction L, respectively, and may be electrically connected to the exposed end portions of the first and second internal electrodes 121 and 122, respectively.

The first and second band portions 131b and 132b may be extended from the first and second body portions 131a and 132a, respectively, to cover portions of a mounting surface of the ceramic body 110 or portions of the upper surface and opposite side surfaces of the ceramic body 110.

Meanwhile, plating layers (not illustrated) may be formed on the first and second external electrodes 131 and 132.

For example, the plating layers may include first and second nickel (Ni) plating layers each formed on the first and second external electrodes 131 and 132 and first and second tin (Sn) plating layers each formed on the first and second nickel plating layers.

The first and second insulating layers 141 and 142 may include first and second vertical portions 141a and 142a formed on central portions of the body portions 131a and 132a of the first and second external electrodes 131 and 132, respectively.

In addition, the first and second insulating layers 141 and 142 may further include first and second horizontal portions 141b and 142b formed on central portions of upper or lower surfaces of the first and second band portions 131b and 132b of the first and second external electrodes 131 and 132, respectively, if necessary.

The first and second horizontal portions 141b and 142b may serve to suppress solders from being formed at central portions of the first and second band portions 131b and 132b of the first and second external electrodes 131 and 132 at the time when the multilayer ceramic capacitor 100 is mounted on a circuit board.

Here, the first and second vertical portions 141a and 142a and the first and second horizontal portions 141b and 142b may have the same width.

The first and second insulating layers 141 and 142 may be formed by applying an insulating material such as an epoxy resin onto one or more selected regions of the central portions of the first and second body portions 131a and 132a of the first and second external electrodes 131 and 132 or the upper or lower surfaces of the first and second band portions 131b and 132b of the first and second external electrodes 131 and 132, but are not limited thereto.

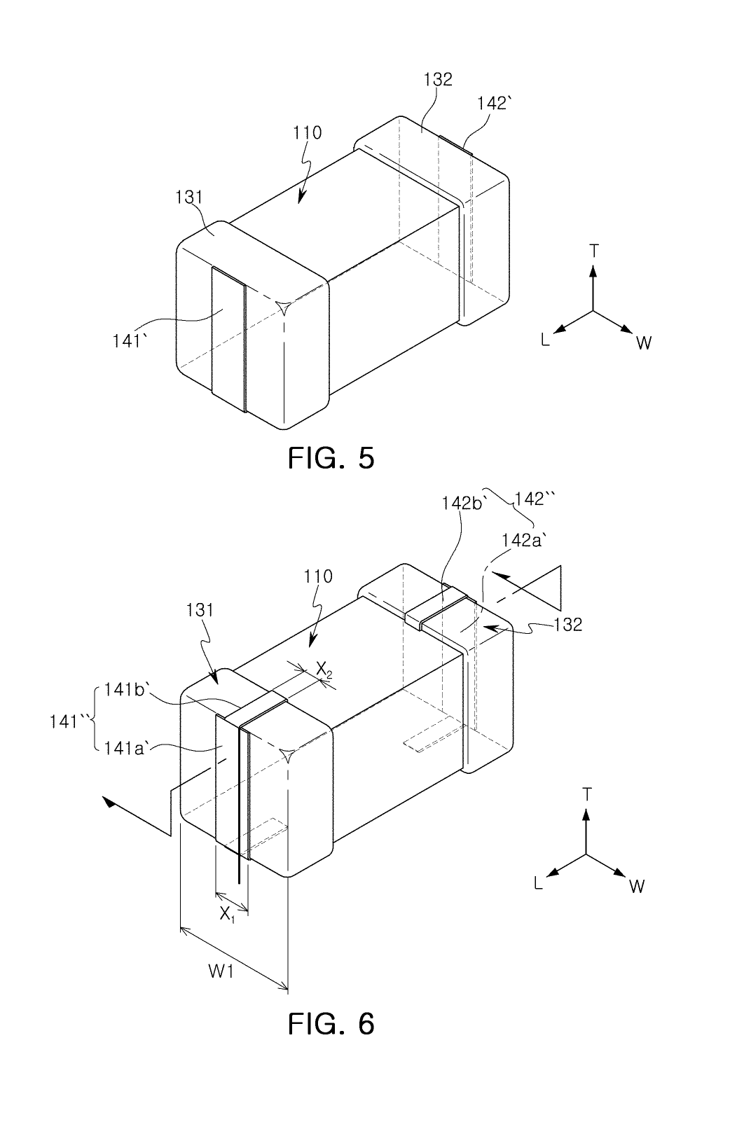

Meanwhile, as illustrated in FIG. 5, first and second insulating layers 141′ and 142′ maybe formed on only the central portions of the first and second body portions 131a and 132a of the first and second external electrodes 131 and 132 and may not be formed on the first and second band portions 131b and 132b, if necessary.

According to the aforementioned embodiments, the first and second external electrodes may include portions exposed by the first and second insulating layers. The exposed portions may be located at opposite sides of a respective insulating layer.

FIG. 6 is a perspective view of a multilayer ceramic capacitor according to another exemplary embodiment.

Here, since structures of the ceramic body 110, the first and second internal electrodes 121 and 122, and the first and second external electrodes 131 and 132 are similar to those of the exemplary embodiment described above, a detailed description thereof will be omitted, and first and second insulating layers 141″ and 142″ will be mainly described.

Referring to FIG. 6, first and second vertical portions 141a′ and 142a′ and first and second horizontal portions 141b′ and 142b′ of the first and second insulating layers 141″ and 142″ may have different widths.

In detail, each of the first and second vertical portions 141a′ and 142a′ of the first and second insulating layers 141″ and 142″ may have a width larger than that of each of the first and second horizontal portions 141b′ and 142b′ of the first and second insulating layers 141″ and 142″.

That is, when a width of the ceramic body 110 is W1, a width of each of the first and second insulating layers 141″ and 142″ formed on the first and second body portions 131a and 132a of the first and second external electrodes 131 and 132 is X₁, and a width of each of the first and second insulating layers 141″ and 142″ formed on the first and second band portions 131b and 132b of the first and second external electrodes 131 and 132 is X₂, W1>X₁>X₂ may be satisfied.

In this case, since bonded areas between the multilayer ceramic capacitor and solders on the lower surfaces of the first and second band portions 131b and 132b of the first and second external electrodes 131 and 132 are increased by decreased widths of the first and second horizontal portions 141b′ and 142b′ of the first and second insulating layers 141″ and 142″, adhesive strength between the board and the multilayer ceramic capacitor through the solders at the time when the multilayer ceramic capacitor is mounted on the board may be improved.

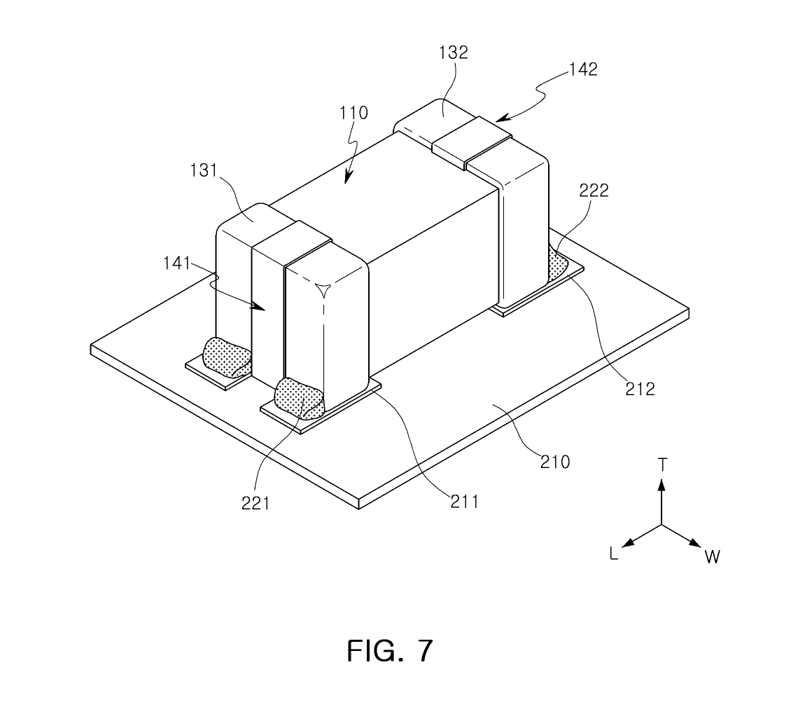

FIG. 7 is a perspective view of a board having a multilayer ceramic capacitor according to an exemplary embodiment.

Referring to FIG. 7, a board 200 having a multilayer ceramic capacitor 100, according to the present exemplary embodiment, may include a circuit board 210 on which the multilayer ceramic capacitor 100 is mounted and first and second electrode pads 211 and 212 disposed on an upper surface of the circuit board 210 to be spaced apart from each other in a length direction L of the circuit board 210.

Here, the multilayer ceramic capacitor 100 maybe bonded and electrically connected to the circuit board 210 by solders 221 and 222 in a state in which the lower surfaces of the first and second band portions 131b and 132b of the first and second external electrodes 131 and 132 of the ceramic body 110 are positioned on the first and second electrode pads 221 and 212, respectively, to be connected to the first and second electrode pads 211 and 212, respectively. Here, the first and second electrode pads 221 and 212 may be divided into two parts in the width direction in relation to the first and second insulating layers 141 and 142, respectively, and may be disposed to be spaced apart from each other in a width direction W of the circuit board 210.

As described above, when voltages having different polarities are applied to the first and second external electrodes 131 and 132 formed on opposite end surfaces of the multilayer ceramic capacitor 100 in a state in which the multilayer ceramic capacitor 100 is mounted on the circuit board 210, the ceramic body 110 may be expanded and contracted in the thickness direction T due to an inverse piezoelectric effect of the dielectric layers 111, and both end portions of the first and second external electrodes 131 and 132 may be contracted and expanded as opposed to the expansion and the contraction of the ceramic body 110 in the thickness direction T due to a Poisson effect.

The above-mentioned contraction and expansion of the ceramic body 110 may generate vibrations, which are transferred to the circuit board 210 through the external electrodes and the solder. Therefore, sound in the form of the acoustic noise may be radiated from the circuit board 210.

In addition, a phenomenon in which the solders 221 and 222 go up along the first and second external electrodes 131 and 132 at the time of reflow may occur.

According to the present exemplary embodiment, by applying the solders 221 and 222 to outer sides of the body portions of the first and second external electrodes 131 and 132 divided by the first and second insulating layers 141 and 142, heights of the solders 221 and 222 and areas of the solders 221 and 222 contacting the end surfaces of the first and second external electrodes 131 and 132 may be decreased. Therefore, propagation of displacement of the multilayer ceramic capacitor 110 to the circuit board 210 may be decreased to decrease acoustic noise.

Particularly, in a multilayer ceramic capacitor having a structure in which the dielectric layers and the internal electrodes are stacked perpendicularly to the mounting surface, maximum displacement of the multilayer ceramic capacitor in the direction perpendicular to the mounting surface may be concentrated on central portions of the body portions of the external electrodes.

In the present exemplary embodiment, since a phenomenon in which the solders are applied to portions on which the maximum displacement is concentrated is prevented by the first and second insulating layers 141 and 142, the propagation of the displacement of the multilayer ceramic capacitor 100 to the circuit board 210 may be effectively decreased, and thus acoustic noise may be further decreased.

As set forth above, according to exemplary embodiments, the insulating layers may be formed on the central portions of the body portions of the external electrodes to be perpendicular to the mounting surface, respectively, to allow the solders to be separated into and formed at both sides of the external electrodes in relation to the insulating layers when the multilayer ceramic capacitor is mounted on the circuit board, thereby preventing the solders from being formed on the central portions of the body portions of the external electrodes and decreasing a height and an amount of the solders formed on the external electrodes. Therefore, a transfer of displacement of the multilayer ceramic capacitor to the circuit board through the solders may be decreased to decrease acoustic noise.

While exemplary embodiments have been shown and described above, it will be apparent to those skilled in the art that modifications and variations could be made without departing from the scope of the present invention as defined by the appended claims.

What is claimed is:

1. A multilayer ceramic capacitor comprising:
a ceramic body including a plurality of dielectric layers and first and second internal electrodes disposed to be alternately exposed in a length direction with at least one of the dielectric layers interposed therebetween;
first and second external electrodes disposed on opposite end portions of the ceramic body in the length direction and connected to the first and second internal electrodes, respectively; and
first and second insulating layers disposed on central portions of body portions of the first and second external electrodes to be perpendicular to a mounting surface of the ceramic body, respectively.

2. The multilayer ceramic capacitor of claim 1, wherein the first and second insulating layers extend to central portions of band portions of the first and second external electrodes disposed on the mounting surface, respectively.

3. The multilayer ceramic capacitor of claim 2, wherein the first and second insulating layers extend to central portions of the band portions of the first and second external electrodes disposed on a surface of the ceramic body opposing the mounting surface thereof, respectively.

4. The multilayer ceramic capacitor of claim 2, wherein the first and second insulating layers have the same width on the body portions and the band portions of the first and second external electrodes.

5. The multilayer ceramic capacitor of claim 2, wherein the first and second insulating layers have different widths on the body portions and the band portions of the first and second external electrodes.

6. The multilayer ceramic capacitor of claim 5, wherein W1>X₁>X₂ is satisfied, in which W1 is a width of the ceramic body, X₁ is a width of the first and second insulating layers disposed on the body portions of the first and second external electrodes, and X₂ is a width of the first and second insulating layers disposed on the band portions of the first and second external electrodes.

7. The multilayer ceramic capacitor of claim 1, wherein the first and second insulating layers are formed of an epoxy resin.

8. The multilayer ceramic capacitor of claim 1, wherein exposed portions of the first and second external electrodes by the first and second insulating layers are located at opposite sides of the first and second insulating layers, respectively.

9. The multilayer ceramic capacitor of claim 1, further comprising first and second plating layers disposed on the first and second external electrodes, respectively,
wherein the first and second plating layers are interposed between the first and second external electrodes, and the first and second insulating layers, respectively.

10. The multilayer ceramic capacitor of claim 1, wherein each plating layer includes a nickel layer and a tin layer.

11. A board having a multilayer ceramic capacitor, comprising:
a circuit board having a plurality of electrode pads disposed thereon; and
the multilayer ceramic capacitor of claim 1 mounted on the circuit board by connecting the first and second external electrodes and the electrode pads to each other.
